(19) United States
(12) Patent Application Publication
(10) Pub. No.: US 2022/0004902 A1
(43) Pub. Date: Jan. 6, 2022

(54) METHODS FOR REMOTE BUILDING INTELLIGENCE, ENERGY WASTE DETECTION, EFFICIENCY TRACKING, UTILITY MANAGEMENT AND ANALYTICS

(71) Applicant: Energy Optimization System Laboratories LLC, McKinney, TX (US)

(72) Inventor: Salem Nayel ALHELO, McKinney, TX (US)

(21) Appl. No.: 17/365,993

(22) Filed: Jul. 1, 2021

Related U.S. Application Data
(60) Provisional application No. 63/047,739, filed on Jul. 2, 2020.
(60) Provisional application No. 63/058,974, filed on Jul. 30, 2020.
(60) Provisional application No. 63/136,937, filed on Jan. 13, 2021.

(51) Int. Cl. G06N 5/04; G06N 5/02; G06Q 30/02; G06Q 50/06; G06Q 10/00; G01R 22/06; H02J 13/00

(52) U.S. Cl. CPC G06N 5/04; G06N 5/025; G06Q 30/0202; G06Q 30/0201; H02J 13/00006; G06Q 10/20; G01R 22/06; H02J 13/00002; G06Q 50/06

(57) ABSTRACT

A system and method of tracking energy usage is disclosed. The system utilizes a variety of tools including periodicity and normalizing of data based on weather and building usage, to obtain more accurate and relevant energy and utility data. This allows the user to more readily find and locate energy waste, which allows the user to remedy the waste event. This reduces energy and utility costs.

### PRIORITY

The present application claims benefit of U.S. Provisional Application No. 63/047,739 filed Jul. 2, 2020; U.S. Provisional Application No. 63/058,974, filed Jul. 30, 2020; and U.S. Provisional Application No. 63/136,937, filed Jan. 13, 2021, all of which are hereby incorporated herein by reference in their entirety and made part of the present application.

### BACKGROUND OF THE INVENTION

### Technical Field

The present invention relates to a system and method for predicting remotely gathering data and make predictions about buildings including methods for tracking utilities, utility management, meter insights and diagnostics of building issues.

### Description of Related Art

Gas, electric, district cooling, and other utility meters can measure and report consumption data. However, this unnormalized unprocessed meter data (IDR) is often too variable to be insightful. Various factors, such as weather and level of building use, yield meter interval data limited in its ability to produce actionable knowledge; currently limited to very few narrow use cases. This problem of knowledge extraction from meter interval data is present at multiple levels. First it is an issue for the building engineer or homeowner due to data availability and complexity of analysis. But the issue is even harder to solve for off-site third-party entities such as utility companies, cities, smart cities, and third-party technology and service providers. Consequently, there is a need for a system and method to extract various forms of knowledge about buildings from various big data sources including meter interval data that can be utilized by one building/home or at a mass scale such as utility companies, cities, and other third-party technology and service providers. Such method and system acquire varies forms of data in conjunction with the meter interval data, then intelligently analyzes all data to extract knowledge buildings operations such as identify waste, find trends, derive insights about each meter load, and diagnose operational conditions of the building. The extracted knowledge can be used in many forms for various purposes. Thus, this method and system includes integration and coupling with multiple related technologies and applications.

### BRIEF DESCRIPTION OF THE DRAWINGS

The novel features believed characteristic of the invention are set forth in the appended claims. The invention itself, however, as well as a preferred mode of use, further objectives and advantages thereof, will be best understood by reference to the following detailed description of illustrative embodiments when read in conjunction with the accompanying drawings, wherein:

FIG. 1 is a block diagram of an embodiment of the present tracking system;

FIG. 2 is a table of energy consumption with various scenarios;

FIG. 3 illustrates an example of modes of operation for a building.

FIG. 4 is a flow chart demonstrating logic around periodicity in one embodiment;

FIG. 5 illustrates calculation methods for various steps in the system in one embodiment.

FIG. 6 Illustrates an example of a Condition-Boundary Text

FIG. 7 illustrates the logic of the Boundary-Condition Test Method

### DETAILED DESCRIPTION

Several embodiments of Applicant's invention will now be described with reference to the drawings. Unless otherwise noted, like elements will be identified by identical numbers throughout all figures. The invention illustratively disclosed herein suitably may be practiced in the absence of any element which is not specifically disclosed herein.

In one embodiment a system is disclosed which detects potentially avoidable energy consumption opportunities. The system can provide extensive analytics and reporting metrics. The system can include meters, hardware, cloud-based centralized platform/software, databases, algorithms, methods of use, different applications, live and static data sources, APIs, online published information, and location data aggregation and sources.

As will be described, while meters can provide data, unnormalized meter data is very variable and unreliable due to a number of factors. The data collected prevents the user from knowing how well the building is using energy and how much of that energy is waste.

The data gathered does not lend itself to an apples-to-apples comparison due to factors such as weather. If data is compared from one year to the next, because the weather can change, the HVAC use, for example, can also change. When an increase in consumption is observed it is difficult to know if that is due to the weather or through faulty equipment. It is also difficult to determine how long the waste had occurred.

In one embodiment, the system normalizes these factors to render the data useable. In one embodiment, this involves gathering weather data, as one example, as well as building usage data, to send to the platform for normalization. This data can be gathered by any means known in the art including obtaining the data from local sensors or remote sources. The system allows data to be converted to “kWh per degree per unit produced” or other similar metric. This metric is more meaningful as it allows a truer comparison with historical data or with other similar buildings. Once normalized data is compared on a similar basis, many insights can be revealed including probable hourly waste.

In one embodiment the system and method comprises a plurality of steps, discussed in more detail below.

The system provides normalization for demanding factors such as weather and building usage. As used herein, demanding factors are those factors, such as weather and building usage, which impact the energy system by requiring more or less lighting, cooling, heating, etc. Historical utility data, along with the associated measured, gathered or inferred demanding factors, are stored in a database. The data can be stored locally or in the cloud. Storing the historical utility data as well as the associated demanding factors along with information about the building being served (business hours, type of buildings, etc.) provides information for a predictive analysis, discussed herein below. In one embodiment at least two demanding factors are stored with the historical utility data. As discussed below, in some embodiments, associating the historical utility data with but a single demanding factor often leads to inconclusive and inconsistent predictions.

The system then predicts the appropriate utility usage based on the demanding factors and the information we have for each building. In one embodiment the prediction is based on at least two demanding factors. The methods of the predictions can vary, and some of them are discussed herein below. In one embodiment the system estimates the reasonable energy usage, such as kWh, for the current demanding factors. The system estimates the reasonable value of consumption given the current demand factors. The system can further estimate the hourly waste. Waste, as used herein, refers to a utility which is not being used for its intended purpose or which is not being properly used (i.e. a utility consumption that can be avoided without impacting the building operation. As an example, lights being on when no one is in a building is a possible example of waste. Further, excess heating when no one is in the building is an example of waste. Further, excess cooling during low occupancy business hours and mild weather is an example of waste. Other examples include increased utility consumption due to electrical faults, leaks in water, gas, or steam lines, or other maintenance issues. Decreasing the waste in a utility system increases the efficiency of that system. If that system is an energy system, then increasing the efficiency of the building, for example, reduces operational energy costs as well as conserves energy, and in turn helps the building owner as well as the utility company and the grid.

Hourly waste, in one embodiment, is the difference between the measured values at the meter (kWh), and the estimated/predicted value of reasonable consumption. The system then, in one embodiment, detects and tracks waste using periodicity. In one embodiment the target waste is a time-specific event with a reoccurring pattern as opposed to a single spike/occurrence. The system also provides for integration with other internet of things devices/ticketing systems to provide a measure of performance or waste associated with any time-bound system.

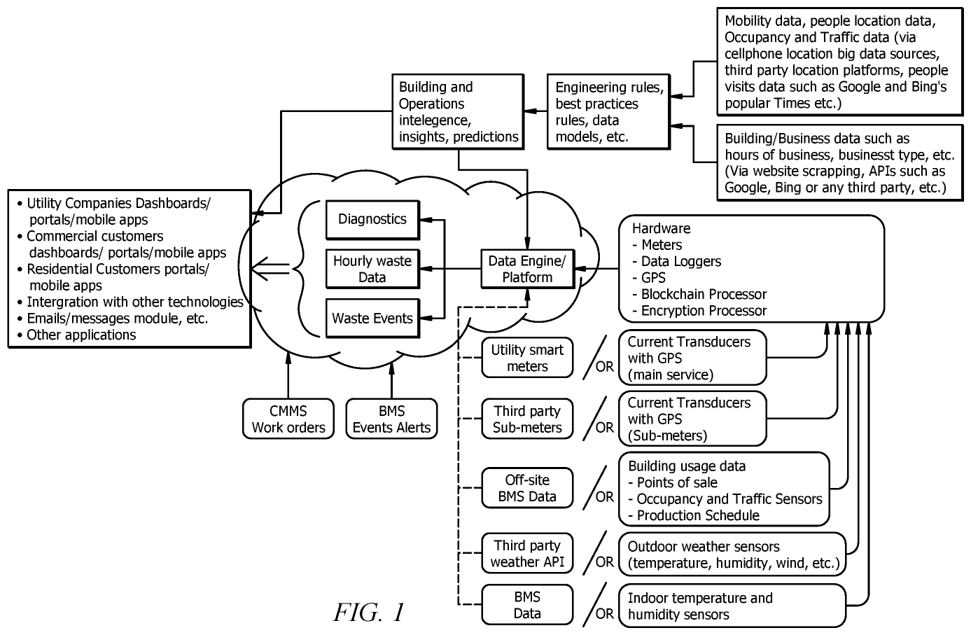

FIG. 1 is a block diagram of an embodiment of the present building data intelligence engine. While the term “tracking system” is used, this is for illustrative and simplicity purposes only and should not be deemed limiting. As noted, the system has many other purposes other than tracking. Just one example is virtual commissioning which is discussed herein.

As noted in FIG. 1, the meter reads and measures consumption of utilities. In one embodiment the meter reads the consumption of energy—gas, electricity, etc. While one embodiment is discussed in reference to an electrical meter, this is for illustrative purposes only and should not be deemed limiting. The system can be used to monitor the usage of virtually any utility source including electricity, natural gas, propane, district cooling, water, and other gas and heat energy. Thus, the associated metered utility data can be data related to water, gas, propane, steam, electricity, and virtually any utility. Furthermore, there is no requirement that the electrical source comprise the grid. This system can be utilized on renewable energy sources such as buildings which obtain partially, or in full, power from solar, wind, thermal, or other such sources.

In one embodiment the meter measures energy consumption at least once every hour. In other embodiments, the interval is less than one hour.

As noted in FIG. 1, the system can monitor demanding factors. As noted, this can include weather and building usage data. When demanding factors increase, so too does the hourly energy consumption. The demand factors can be measured on site via dedicated sensors, through integration with other business systems, uploaded manually to the platform, or through third party sources that aggregate people location and business data.

In one embodiment, the system takes into consideration the current level of building usage to leverage in managing energy and utilities. Especially in buildings where occupancy level is a critical demanding factor, occupancy level can be predicted by using GPS traffic data, cellphone location data, or popularity hours indicators such as Google Popular Times or similar sources. Building usage level data can be obtained from databases, API's, scrapping of internet pages, or other methods.

As shown in FIG. 1, the system includes local and connected weather sensors which can record the outdoor and indoor weather, including temperature and humidity. The system can also include remote weather sources. Weather data can be measured by the system itself, through integration with the building management system, or through cloud third party services.

As shown in FIG. 1, the system includes local occupancy sensor/business systems and traffic sensors, as well as connected occupancy and people location/traffic data; which can record the number of people in the building for each utility meter reading. Occupancy/traffic level can be measured in number of people or as a metric or percent to indicate the building usage level.

In some embodiments, and as depicted, the system comprises a BMS, or Building Management System. The BMS is the automation or control system of the building systems that are viewed and/or controlled via software/platform. These systems can include HVAC and lighting, sensors, actuators, controllers, etc. The data from the BMS controls includes records which may impact energy waste levels. Accordingly, including data from BMS improves the decision-making process for operating the building.

As shown in FIG. 1, in some embodiments the system further includes integration/overlaying with CMMS, or Computerized Maintenance and Management System. A CMMS, in one embodiment, is software/platform where repair, requests, and other maintenance related tasks are recorded and managed, such as in the form of tickets or work orders. The CMMS records failures that may have contributed to the energy waste levels. Like with the BMS, the system improves the decision-making process in the CMMS and operation of the building.

FIG. 1 also records building usage data. In one embodiment, building usage data is a specific metric which indicates how productive the building is or how much it is being used. The metric can take many forms. For a manufacturing facility the metric can reflect number of units produced. For a school, the number of students can be the metric. A retail store may indicate the number of customers. For a building, the metric may be the number of occupants. In one embodiment, building usage is a demanding factor.

The hardware used in the system can vary depending upon the specific application. In one embodiment the hardware comprises meters, data loggers, and sensors. In one embodiment the hardware can record interval consumption data with a pulse rate of up to 1 minute. In one embodiment the data logger can save data during a loss of connectivity from the cloud which is resent when a connection is re-established.

In one embodiment the hardware can connect to a plurality of indoor and outdoor temperature and humidity sensors. In one such embodiment the data is recorded every minute. Time can be kept locally, but in one embodiment the hardware is tied to the astronomical clock to ensure accurate and correct time.

Many different types of processors can be utilized. In one embodiment the processor has the ability of blockchain processing of data as well as data encryption.

The system can have many other features which aid to the usability of the system. One example is GPS capability. In one such embodiment a visual mapping of the building is available through the Building Information System BIM or similar mapping tools or phone/handheld applications so that once a waste is detected, the technician will be able to locate the specific meter or hardware via GPS mapping.

In one embodiment the hardware can connect with a plurality of databases and data sources as previously described. This can include the weather database, mobility data (people location data), GPS databases, building usage databases, utility meter databases, utility billing database, business schedules database (such as google maps, internet scrapping, etc.), business traffic database (such as Google's Popular Times), etc. The system can pull the necessary data from the relevant databases.

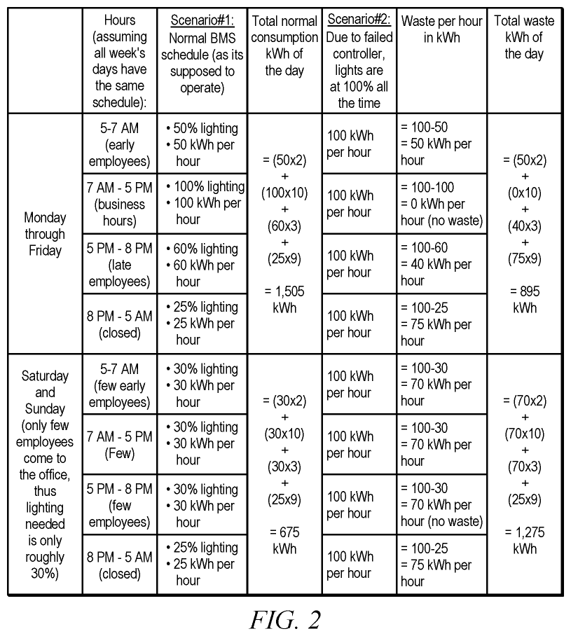

As noted, the system normalizes data. In doing so, the system can detect and account for various variability in the demanding factors. Waste often occurs at an intermittent pattern as demonstrated in FIG. 2. Thus, the economic and environmental impact of a waste issue cannot be properly defined by estimating waste magnitude at a specific period, neither it can be tracked that way for a longer period. Periodicity is the pattern of waste that is measured by the combination of the three variables: quantity of waste, cadence of occurrence (cycles), and hours of the day of the week. Periodicity is the foundation of identifying and tracking waste trends and events accurately.

FIG. 2 is a table of energy consumption with various scenarios. In Scenario 1 is the normal schedule. In Scenario 2, there is one waste cause—a faulty controller. Even though there is only a single waste cause, the waste values vary depending upon the time of day, number of occupants, etc. This demonstrates that the criteria which triggers a waste alarm should account for the trend of waste among the hours, days, amount of waste, persistence of the issue, etc.

In FIG. 2, the waste event will continue until the controller is fixed. As noted, the waste per hour varies depending upon the time of day. This results in a pattern. Waste events often have patterns which are tied to the operational nature of the building served. Periodicity includes hours of the day of the week, quantity of waste, cycles (number of wasteful days per week/7 days).

The waste fluctuations depend upon the building's mode of operation. Buildings operate on a schedule based in part on the opening time, closing time, timing of building operations, etc. The building operation also relies upon the building automation system which includes lighting schedules, heating and cooling schedules, etc.

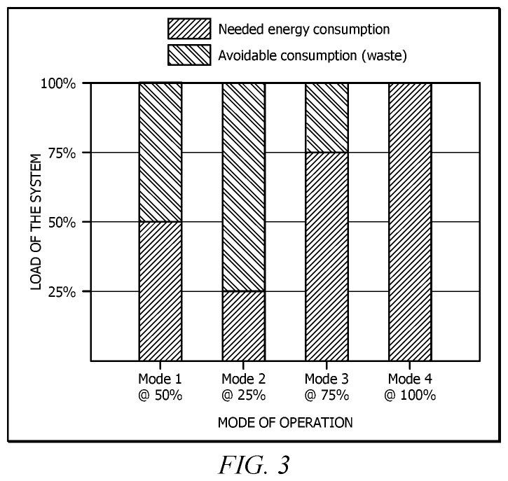

FIG. 3 illustrates an example of modes of operation for a building. If in mode 1 the building needs 50% of the lighting capacity to be on, and a faulty controller is causing 100% of lighting to be on, then the waste at mode 1 is 50%. Thus, the amount of waste will depend upon the modes of operation of a building.

As noted, waste is cyclic. If there are four modes of operation for a building, the building will cycle through all four modes every day (per the operation schedules; which can be every week, every 10 days, etc.). Because waste follows the modes of operation, waste is cyclic just like the pattern of modes on daily and weekly bases (or other schedules).

In one embodiment, the system takes into consideration the current mode of operation as it relates to the business hours/building schedule. Building schedule can be obtained directly from the building operators, or indirectly through published hours. Building schedule can be obtained from databases, API's, scrapping of internet pages, or other methods.

In one embodiment the system detects anomalies based on normalized kWh rather than metered kWh. This decreases the effect of variation due to the demanding factors. This allows for discerning with better accuracy the loads which are potentially avoidable.

In one embodiment, the system provides for meter specific algorithms to normalize and estimate hourly waste tied to a specific meter. This allows the system or user to select algorithms, assumptions, and methods to best fit the specific meter. This customization of the algorithm for each meter can be done based on the type of building, size, etc. or automatic through artificial intelligence clustering algorithm. These specific algorithms and assumptions are likely to vary when the building is a school versus a manufacturing facility, etc. Taken further, the algorithms, assumptions, etc. for a sub-meter servicing an HVAC system is different than the sub-meter servicing lightning loads. As but one example, the lighting loads may be significantly less impacted by weather than the HVAC system. In one embodiment, the system allows for estimating the reasonable consumption under the current conditions using one of many different methods.

When monitoring a portfolio of a large number of buildings or meters, using a single criterion to detect waste is ineffective. Applying a single criterion to detect threshold based anomalies, for example, and applying those to the entire meter can result in many false alarms as well as missing other waste events. As an example, if the kWh reading from the meter exceeds the threshold, an alarm will be generated. However, some wasteful meters have loads below the threshold resulting in false negative alarms. While other meters will serve needed loads that at times will be well over the threshold, due to normal demanding factors, resulting in false positive alarms. Accordingly, when monitoring many meters with wide range of loads, one criterion for alerts fails to detect all waste opportunities and creates false positive alarms. In one embodiment the system herein allows for periodicity-based, meter-specific alert criteria. This improves the effectiveness of identifying waste opportunities within the entire portfolio.

As noted, the system allows periodicity to be monitored and tracked. This allows for waste results which are focused on a specific group of hours and/or specific days of the week depending upon the application. For example: this can be to track waste of buildings in a utility company's territory during the peak load hours. The user can select and monitor waste specific operations such as school day, after school hours, cleaning crew hours, commodity trading hours, peak load hours etc. This allows the user to target specific waste issues dealing with specific time periods which can yield monetary savings. Periodicity allows for waste to be observed or corrected that occurs on a cyclic pattern rather than one-time anomalies which may or may not persist. Additionally, periodicity detects waste events more accurately by excluding false positives and false negatives than other tool since they do not normalize against other demanding factors.

Turning back to FIG. 1, FIG. 1 shows alerts. In one embodiment alerts are shown on the user dashboard and can be communicated to the appropriate individual or team via any communication medium (text, email, etc.). The alerts and waste event metrics can be shown on the CMMS work orders interface. The alerts and waste event metrics can also be shown on the BMS interface as well as be assigned waste values for different BMS fault alarms.

In one embodiment the system is usable as a stand-alone system to monitor the inefficiency and waste of metered energy loads. The analytics, in some embodiments, can be correlated to other events—such as BMS or CMMS events. If the system estimates there is a wasteful event that is active during a specific period, this information can be used to isolate and diagnose the problem. If, for example, during the same period the BMS system indicated there are 3 failures or control alarms, the system can presume that one or more of the BMS failures are responsible for the energy waste events.

As noted, the system utilizes normalization to obtain less variable and more accurate prediction. In one embodiment the energy data is normalized against the weather. If only tracking seasonable energy consumption, data can be normalized against heating and cooling degree days. However, this fails to normalize consumption data that is measured at intervals shorter than a day (hourly, minutes, etc.). In one embodiment, to track waste in an operational fashion, normalization is completed at the hourly level. The weather data can be recorded locally from a sensor or remotely from a third-party weather provider API (or other methods). This results in an improved metric which reflects waste at each hour. When this is combined with periodicity, more accurate alarms can be achieved. This means less false alarms, and increased relevant alarms.

The system and method can be implemented with various types of software, coding, etc. In one embodiment the system utilizes blockchain coding. In one embodiment the hardware comprises the ability to allow blockchain coding of energy associated with waste versus what is needed for operation. As an example, if the building receives a specific portion of green energy and there is a commitment that green is used optimally, blockchain can provide the answer as to where and how efficiently the green energy has been used.

The normalization process can comprise many different statistical methods to normalize the data. As noted, in one embodiment the algorithm will normalize the consumption data by including weather and building usage. For a given period of time, such as every hour, as a non-limiting example, the algorithm will predict the appropriate kWh for that period's demanding factors. The prediction can follow different statistical methods and engineering principles, which can be selected by the user or automated by artificial intelligence.

As noted, the normalization process can utilize a number of methods to calculate predicted consumption. In one embodiment the system utilizes several of such methods in the calculation. In but one example, in one embodiment the system uses the regression method. In this method, the system uses the same data from the previous year, for example, and then applies the demanding factors to that specific time period. In another embodiment; the system uses multivariate regression of historical data to predict the consumption. In another embodiment the system utilizes an Z-score upper limit whereby the user assumes that the consumption should not exceed X % of the historical efficiency. The user specifies the upper limit, and the algorithm calculates the normalized kWh for each of period, such as an hour, of the week that corresponds to the specified upper limit. The algorithm will take the calculated normalized kWh and apply the demanding factors to calculate the prediction consumption, Y. The result is that X % of the time the consumption for that hour of that day will not exceed Y kWh. The method can be used in combination of each other for the appropriate application. The selection of the methods used can be done by the user or through artificial intelligence.

In one embodiment, the system predicts the consumption by referencing times with similar operating conditions to establish a “Bestline” for each hour specifically. As non-limiting example: the system will compare the current hour with similar hours (or range of hours) that had similar weather conditions, demanding factors, and operational conditions. Once an average, a range, or an appropriate predicted consumption value(s) is established, hourly waste can be estimated by measuring the difference between the metered value and the predicted value(s).

Similar to normalization methods, in one embodiment the system utilizes methods/models to predict the appropriate consumption values giving the current operating conditions.

In another embodiment the system uses machine learning. In such an embodiment the algorithm learns on the available data history and establishes relationships between variables and the energy consumption. This method can be applied to the non-normalized kWh against all other variables or applied on the normalized kWh against all other variables excluding the demanding factors used in the normalization.

It should be noted that these statistical tools are used for illustrative purposes only and should not be deemed limiting. Further, while they are described separately, two or more tools can be used simultaneously. As an example, machine learning can be used to augment other approaches. In still other embodiments two or more tools are used to predict the approach, and a blended path is selected. Or new method can be developed to best suit a specific type of building and application.

The algorithm further calculates the waste. The algorithm can apply periodicity, as previously described, to generate alarms, define the beginning and end of waste events, and diagnose problems.

The end result is that the system provides insight on how optimally the building, or system, is running for a period of time, such as an hour. If the gap between the actual efficiency and the desired efficiency is significant, additional investigation is warranted.

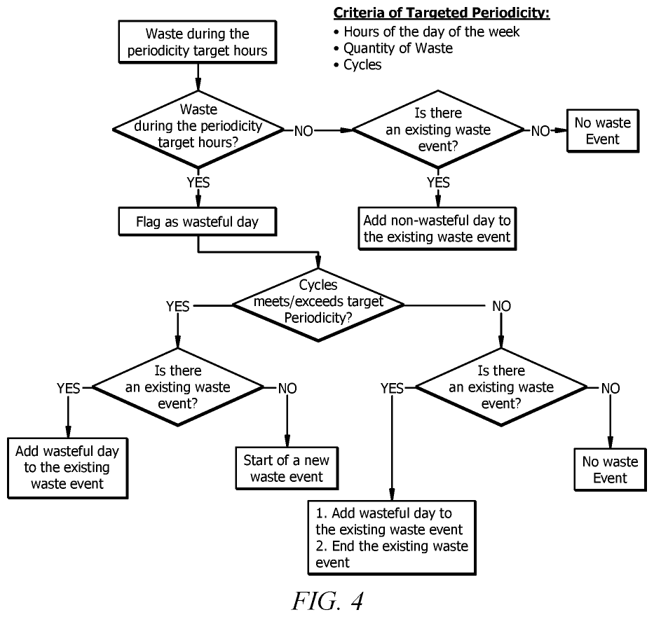

FIG. 4 is a flow chart demonstrating logic around periodicity. This is an example of the logic behind reviewing and treating periodicity.

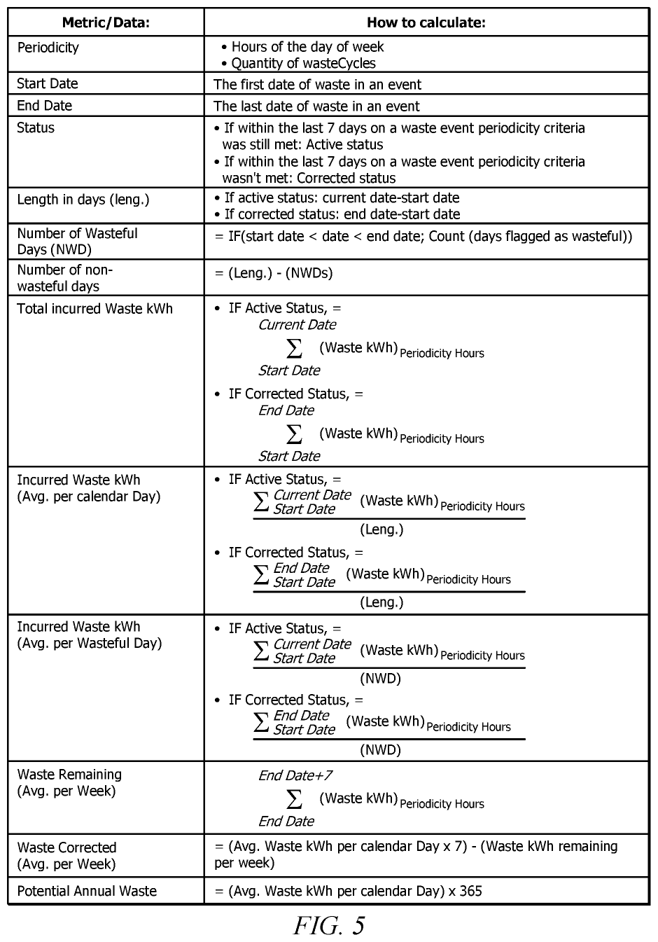

FIG. 5 illustrates calculation methods for various steps in the system in one embodiment. FIG. 5 illustrates one calculation method and is for illustrative purposes only and should not be deemed limiting.

FIG. 5 illustrates one advantage of the system and method discussed herein. Because the system discussed herein is much more accurate than previous systems, the system can be used to monitor, predict, and correct waste. Waste in a specific system can be quantified as a financial cost. Therefore, correcting and stopping the waste can be quantified as a financial savings. This allows users of the system to see and understand the financial, as well as the environmental, impact of the system. Due to the wildly inaccurate prediction in other systems, this is an advantage which the prior art failed to obtain.

As noted, one advantage of the system discussed herein is the identification of waste. When waste issues are addressed, it reduces waste energy. This results in a more efficient, and more environmentally friendly, building. It has the additional benefit of reducing energy costs. Energy costs often have more of an impact than simply utility bills. For example, when renting commercial space, the tenant is often responsible for their portion of the utilities. By having a comparatively lower utility bill, the building owner will be able to present potential tenants with more competitive pricing than other building owners who have not used the system discussed herein.

In one embodiment, the system can be used to assess the meter data hosted by utility service provider, utility companies, etc. where the assessment can be done by leveraging indirect and public data sources such as Google, GPS and location/mobility data, and mapping services, cellphones tracking data, etc. In this embodiment, the analytics can be applied at the utility data warehouse by correlating the meter data, along with business schedules, weather data, occupancy level, etc. to assess the waste levels of each hour for each building/meter. Utility companies or utility data warehouses can utilize this system to generate alarms to notify customers of possible waste, trends, etc. Additionally, as a non-limiting example, this analysis can be provided by the company's website to each customer through their web portal or mobile application to enhance the usability of meter data.

In one embodiment, the system can be used to conduct virtual commissioning of the buildings. Where the energy usage schedule (AKA energy profile) can be correlated and compared to the business schedule, popular times, etc. to spot possible misalignment opportunities that are causing waste.

In one embodiment, the system is used, partially or fully, as the centralized decision-making platform to correlate the key areas needed to operate/service buildings or portfolio of buildings; utility data, CMMS, BMS, building scheduling/event systems, etc. Where all tickets, events, waste, etc. are correlated to any selected time frame. This provides a complete and full picture to the operators on how these areas interact and influence the utility consumption and waste.

The system and method discussed herein will now be illustrated via select examples. These examples are shown for illustrative purposes only and should not be deemed limiting.

Computerized Maintenance Management System

Computerized Maintenance Management System (CMMS) is often the foundation of managing most of the facility related activities from repairs, maintenance, cleaning activities, etc. Many of the building's activities captured in the CMMS are directly or indirectly causing the energy waste. As an example, while a failed door closer may seem not related to energy consumption, the door open will leak air out forcing the air conditioning to run more and consume more energy/utility. Thus, showing energy waste as an indicator on the CMMS will improve the CMMS prioritization and effective decision making. This data will inform the user of the CMMS of the “cost of delay”. The waste data shown in the CMMS work order is a high-level data intended to correlate the work orders to utility consumption.

The data can be shown as an indicator. As an example, the dashboard where the work orders of the entire portfolio are listed, the waste data can be shown through two key data elements. First, the daily or weekly running waste which is the total of waste running rate of all events for each building which is active on the work order starting date forward. The active work orders in the portfolio will be shown with this number, and all values will be on a color scale from the more severe (red) to the lowest waste value (dark green). Second, the likelihood that this specific work order is the major root cause of the waste. This can be shown as a scale where the higher the likelihood, the higher the scale will be. It can be similar to a cellphone bar. Full bar may be 99% whereas 3 bars may represent 77%.

With this type of data CMMS users are able to prioritize the word orders with higher waste values, and those that have a higher likelihood. The CMMS dashboard can sort all work orders by waste amount from high to low, and within the same building, sort work orders with the higher likelihood.

In some embodiments the CMMS will transfer the following data to the system: information for the open WOs; create date of active work orders; create date of active work orders; type of work order such as reactive or PM; service type such as HVAC repair, electrical light, plumbing, etc.; assets such as RTU door, windows, building controls, electrical panels, etc.

In one embodiment the system will return the waste amount which is the running rate of all waste events at each building. It will also return the likelihood of scales of the word order type being related to the running waste. The below table can be created and used by engineering, facility maintenance experts, or energy experts.

| | Likelihood = | Likelihood = | Likelihood = | Likelihood = | Likelihood = |
|---|---|---|---|---|---|
| | 0 (no bar | 1 (1st bar | 2 (2nd bar | 3 (3rd bar | 4 (4th bar |
| | highlighted) | highlighted) | highlighted) | highlighted) | highlighted) |
| | [symbol] | [symbol] | [symbol] | [symbol] | [symbol] |
| Reactive vs PM | PM | Reactive | Reactive | Reactive | Reactive |
| Service | Others | Doors, | electrical | HVAC | Lighting, |
| type/asset: | | windows, | | | controls |
| HVAC, | | | | | |
| Controls, | | | | | |
| electrical | | | | | |
| lighting, others | | | | | |

As seen, if it is a PM, then no bar is highlighted. If reactive, the table can be followed. If the waste amount is zero, then the likelihood will also be zero. The CMMS will show the waste icon for every open WO. It will display the amount, and the likelihood by highlighting the corresponding bar. It will also color the icons based on the amount of running waste or similar benchmarking metric.

Integration with BMS/EMS and Fault Detection Dashboards

The BMS systems monitor controls data points as well as their trends. Through logic rules, faults can be detected. Often, submeters or meters at the equipment level measure energy consumption and an estimate of waste caused by the fault can be made. The system described herein improves the BMS/EMS in many ways. First, the system can provide an estimate of the impact of the faults in a live way. The estimate of waste made by the submeter does not inherently take into consideration the impact of other variables which impact the consumption as noted above. These include weather, occupancy, building schedule, etc.

Second, the system can be used as a method of verification of the impact of a fault and the correction taken. The estimate made in the absence of an isolation meter—like a submeter—is an isolated guess and is not verified by the building consumption. The system provides a correlation between the building activities and the building waste level/trends to better assess the impact of the waste mitigation effort.

Third, the system can be used as a method to prioritize the impact of a fault. This can be done in an approach like that discussed in the integration with CMMS section. The running rate of waste is done based on that of the waste events in the entire building (or meter zone), and the likelihood of fault type to cause higher waste amount. The prioritization will allow the BMS monitoring companies to provide recommendations to their customers that is combined with where to better allocation their repair budget. Also, it will help the BMS monitoring companies to simplify and improve their process efficiency by finding the building that are suffering from higher waste, then identify what are the possible reasons.

Utility Scale Virtual Commissioning

Virtual Commissioning is the process of identifying saving opportunities through the remote view of interval data and other energy related data. An example of a saving opportunity which can be identified by the virtual commissioning is changing the equipment/lighting schedule to match the business schedule.

Utility Scale Virtual Commissioning, in one embodiment, is the process of analyzing the entire Advanced Metering Infrastructure (AMI) data at the utility company level to identify buildings with saving opportunities (such as current waste issues). This enables the utility companies to target their efficiency improvement efforts and marketing efforts to engage customers of buildings with the highest potential of saving and environmental impact.

As an example, utility companies can target commercial buildings which that issues in their setback mode where the building is not modulating down its consumption to the fullest at night. Below is one example of how the system can identify the savings opportunities.

First, determine the minimum amount of waste kWh to target. As an example, assume a 6 hour setback mode waste per night—6*365=2,190 hours per year. If the desired savings is $20k per year per building, then the hourly waste running rate needs to exceed $20k/$0.12/KwK/2,109, or 76.1 of waste kWh per hour during the setback mode.

Next, is identifying the buildings with the possible issues. Through the integration with business hours APIs or scrapping public pages, the businesses that should be on the setback mode at 1, 2, or 3 AM can be identified. This includes all businesses with published business hours, office buildings, schools, municipalities, etc. For each building/meter for the selected hour, the current reading is compared to the historical non-zero values. The variance is calculated between current kWh and historical minimums. Buildings with a variance exceeding 76.1 kWh are possible saving opportunities.

Next, is confirming persistence of the issues. This can be accomplished by counting the number of hours with variance of at least 76.1 kWh. The higher the hours count, the more persistence the issue is.

Additionally, the users can prioritize opportunities. The potential savings is the total of the variance for all hours over the past 12 months during the setback mode hours.

Finally, the users take action. The users can review the data and contact building management. They can send an alert to the building manager via email, text, etc. They can also add this to the next bill. Other approaches can also be used to identify other possible causes of waste such as startup mode initiates too early, setback initiates too late after business operations, etc.

Portfolio Optimized Commissioning

Retro-commissioning addresses individual facilities where all aspects of the facility get commissioned to make sure they operate efficiently as intended. Portfolio Optimized Commissioning, in one embodiment, is where the entire portfolio is being monitored for waste, and the locations with the highest amount/trends of waste are selected for optimized commissioning process. The process focuses on specific lists of causes rather than commissioning the entire building. The insights and trends of waste data along with the diagnostics of the probable issues is used to narrow the scope of the commissioning. This allows for the identification of higher impact issues faster using less resources.

### Schools

If a school offered a 3-hour class in the evening for 2 nights, energy consumption will increase during those hours (let's say increased to 180 kWh for each hour of class). This is typically done by programming the equipment and BMS schedules. However, when the class is completed, the BMS should be programmed back to the normal schedule. If this is not done, consumption during those hours will continue as a wasted energy.

The system expects normal consumption during those hours. In one embodiment, normal consumption for this scenario is predicted considering several different factors. First is baseload. The algorithm analyzes the historical data and estimates the baseload. For illustrative purposes assume a baseload of 50 kWh per hour.

Second is outside temperature. The algorithm analyzes the historical data for those hours and finds that consumption varies by 2 kWh per cooling degrees per hour plus the baseload. For baseline temperature assume an outside temperature of 85° with an neutral temperature of 65° with a delta of 23 cooling degrees.

Third is the occupancy of the school. The algorithm analyses the historical data for those hours and finds that consumption varies by 22 kWh per classroom—20-30 students—per hour.

Fourth is operating mode/schedule. The evening hours are part of the setback mode where no students are normally in the school. Accordingly, in one embodiment the

$$Predicted Normal consumption = ( Baseload ) + ( cooling consumption ) + ( Occupancy consumption ) = ( 50 ) + ( 2 \times 23 ) + ( 22 ) = 118 kWh$$

It should be noted that the method of prediction is only one model among many which the system can use. As noted, in one embodiment the method is tailed to the specific scenario and building type.

In the example above, the system will expect to see the normal consumption of 118 kWh during those hours. When the reading comes in at 180 kWh, higher than expected, the system will log 62 kWh as waste for each hour. If the BMS is not corrected, the building will have a waste during those hours around 62 kWh—which will vary depending on weather. This waste quantity and trend is unknown to the operating team. Some school staff may have seen the lights on some nights, but didn't realize the financial and environmental impact.

One of the system's benefit comes in by converting the raw meter data to clear waste and financial insights. If the targeted periodicity criteria was based on a waste of 100 kWh daily waste and three wasteful days in a week, the system will identify this issue as a waste event after the third night.

The daily waste=62*3=186 kWh (the exact value calculated by the system will vary depending on the changes in weather).

The Annual Projected Waste (kWh)=186*365=67,890 kWh

Financial Impact (Annual projected waste $)=67,890*0.13=$8,825.70 saved annually (at kWh rate of $0.13)

Environmental Impact=(7.07×10⁻⁴ metric tons CO₂/kWh)×(67,890 kWh)=47.998 metric tons of CO₂ saved annually.

### Retail or Restaurants

If a retail or restaurant building has a variable frequency drive that failed and defaulted the motor to it 100% speed. This failure increased the consumption to 280 kWh for the specific hour of HVAC schedule.

The system expects normal consumption during those hours. Normal consumption for this scenario is predicted considering the following variables. First is baseload as described above. We can assume 50 kWh per hour. Second is outside temperature. Assume 23 cooling degrees as above. Third is occupancy of the building. We can assume 1.3 kWh per customer or sale made. Fourth is operating mode/schedule which is tied to all operational modes where the VFD is activated.

$$Predicted normal consumption = ( Baseload ) + ( cooling consumption ) + ( Occupancy consumption ) = ( 50 ) + ( 2 \times 23 customers ) + ( 1.3 \times 30 customers ) = 135 kWh$$

As noted, various methods of prediction can be used. In this scenario the system expects to see the normal consumption of 135 kWh during those hours. When the reading comes in at 280 kWh, higher than expected, the system will log 145 kWh as waste for each hour.

If the VFD is not corrected, the building will have a waste during those hours around 145 kWh—which will vary due to the weather and other factors. This waste quantity and trend is unknown to the operating team. Some staff may have seen the lights on, but did not fully realize the financial and environmental impact.

One of the system's benefits comes by converting the raw meter data to clear waste insights. If the targeted periodicity criteria was based on a waste of 100 kWh daily waste and 4 wasteful days in a week, the system will identify this issue as a waste event after the third night. The waste parameters are shown below.

The daily waste=145*No. of Hours (assume 9 daily)=1,305 kWh (the exact value calculated by the system will vary depending on the changes in weather).

The Annual Projected Waste (kWh)=1,305*52 weeks*6 days where the VFD is scheduled to run)=407,160 kWh

Financial Impact (Annual projected waste $)=407,160*0.16=$65,145 annually (at kWh rate of $0.16)

Environmental Impact=(7.07×10⁻⁴ metric tons CO₂/kWh)×(407,160 kWh)=287.86 metric tons of CO₂ saved annually.

Office Buildings

Consider if the lighting schedule is supposed to shutdown main lighting at 8 PM every day, but the contactors failed to do so. The consumption for the night hours will be roughly 177 kWh higher than what the system is predicting based on the historical data.

The system expects normal consumption during those hours. Normal consumption for this scenario is predicted considering the following variables. First is baseload as described above. We can assume 50 kWh per hour. Second is outside temperature. Assume 23 cooling degrees as above. Third is occupancy of the building. Here the algorithm analyzes the historical data for those hours and finds that consumption varies by 22 kWh per occupant per hour. Fourth is operating mode/schedule which is tied to all operational modes where the lighting is controlled.

$$Predicted normal consumption = ( Baseload ) + ( cooling consumption ) + ( Occupancy consumption ) = ( 50 ) + ( 0.55 \times 23 ) + ( 0 ) = 62.6 kWh$$

As noted, various methods of prediction can be used. In this scenario the system expects to see the normal consumption of 62.6 kWh during those hours. When the reading comes in at 177 kWh, higher than expected, the system will log 114.4 kWh as waste for each hour.

If the lighting controls/contractors are not corrected, the building will have a waste during those hours around 114 kWh—which will vary due to the weather. This waste quantity and trend is unknown to the operating team. Some staff may have seen the lights on, but did not fully realize the financial and environmental impact.

One of the system's benefits comes by converting the raw meter data to clear waste insights. If the targeted periodicity criteria was based on a waste of 100 kWh daily waste and 4 wasteful days in a week, the system will identify this issue as a waste event after the third night. The waste parameters are shown below.

The daily waste=114*10 hours of waste per day=1,140 kWh.

The Annual Projected Waste (kWh)=1,140*365=416,100 kWh

Financial Impact (Annual projected waste $)=416,100*0.13=$54,093 saved annually (at kWh rate of $0.13)

Environmental Impact=(7.07×10⁻⁴ metric tons CO₂/kWh)×(416,100 kWh)=294.18 metric tons of CO₂ saved annually.

Hotels and Hospitals

Consider if a simultaneous heating and cooling are taking place it will cause the consumption to increase more than expected. The system will identify this normalized increase as a waste.

The system expects normal consumption during each hour. Normal consumption for this scenario is predicted considering the following variables. First is baseload as described above. We can assume 1,200 kWh per hour. Second is outside temperature. Assume 25 cooling degrees as above. Third is occupancy of the hospital or hotel. Here the algorithm analyzes the historical data for those hours and finds that consumption varies by 8 kWh per resident/occupant per hour. Fourth is operating mode/schedule.

$$Predicted normal consumption = ( Baseload ) + ( cooling consumption ) + ( Occupancy consumption ) = ( 1 , 200 ) + ( 144 * 25 ) + ( 8 * 1000 occupants ) = 12 , 800 kWh$$

As noted, various methods of prediction can be used. In this scenario the system expects to see the normal consumption of 1,200 kWh during those hours. When the reading comes in at 13,283 kWh, higher than expected, the system will log 483 kWh as waste for each hour.

If the simultaneous heating and cooling issue is not corrected, the building will have a waste during those hours around 483 kWh—which will vary due to the weather. This waste quantity and trend is unknown to the operating team. Some staff may have noticed the faulty valves, but did not fully realize the financial and environmental impact.

One of the system's benefits comes by converting the raw meter data to clear waste insights. If the targeted periodicity criteria was based on a waste of 1,000 kWh daily waste and 4 wasteful days in a week, the system will identify this issue as a waste event after the third night. The waste parameters are shown below.

The daily waste=483*10 hours of waste per day=4,830 kWh.

The Annual Projected Waste (kWh)=4,830*365=1,762,950 kWh

Financial Impact (Annual projected waste $)=1,762,950*0.13=$229,184 saved annually (at kWh rate of $0.13)

Environmental Impact=(7.07×10⁻⁴ metric tons CO₂/kWh)×(1,762,950 kWh)=1,246.4 metric tons of CO₂ saved annually.

In one embodiment the system and methods described herein are used in the application of smart cities where a city administration can gather building intelligence, measure utility/energy waste, track efficacies, etc. to serve the purpose of smart city.

In one embodiment where the system and methods described herein are used at the city/territory level for serving smart city initiatives, the sensors and internet of things IoT can be treated similar to a BMS system in a building.

In one embodiment, the system analyzes the interval data in association with all other data available in the system to diagnose the existence of specific issues in the building and whether such issues are related to a detected waste event.

Previous arts have focused on one approach for diagnosing issues, that is analyzing the signals of the meter readings. Thus, they depend on a high frequency of meter readings that can produce data-rich signals. Such signals can reach milliseconds intervals versus the common 5-to-60 minute interval meters. The prior art's approach in turn renders the majority of the existing smart meter infrastructure today non-ideal for diagnosing issues in buildings. In one embodiment, the system and method discussed herein addresses this issue and enables the use of current common meters, that have minutes-long intervals (5 minutes, 15 minutes, 60 minutes, etc.) to be used for diagnosing issues.

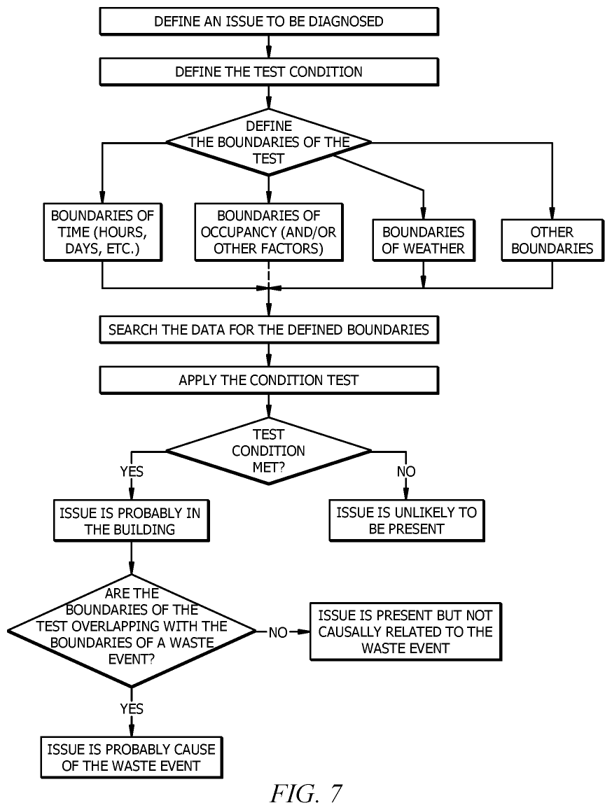

As but one example, the method the system uses is the Boundary-Condition Test Method. See FIG. 7 for the logic of this method in one embodiment. The Boundary-Condition Test Method is a diagnostic method that identifies the probable existence of a predefined issue by evaluating cross-data-type signs. Searching multiple datasets for a specific boundary of data where a conditional test can be performed to evaluate the existence of a condition or issue in the building. The result of the test to the predefined condition(s) at a boundary specific data can find and determine the existence of a potential issue.

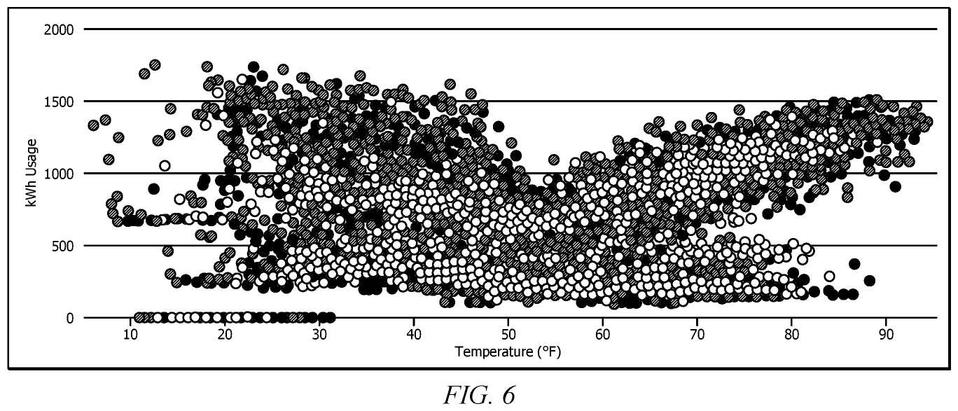

As one non-limiting example, one common issue in buildings is the failed air economizer system or its ineffective settings. The cross-data-type sign of a functional economizer is to have a lower kWh values when the outside air temperature is within the free cooling zone (55 F±5 F). FIG. 6 illustrates the dip in kWh during the free cooling temperature ranges.

In this example, to test for a failed economizer, the system will examine the relationship between meter kWh and outside air temperature for different temperature ranges and modes of building operations. The condition for this test “is the average kWh at outside air temperature of 55 F same as that at 50 F and 60 F?” if the answer is yes, then the air economizer is not working effectively. The boundaries applicable to testing this condition are: temperature range of 50-60 F, schedule off-hours (1-4 AM) or when occupancy is minimum or zero. Once that the Boundary-Condition Test Method confirms a failed economizer function the system will examine whether this issue is the probable driving cause for a specific waste event. That is done by performing the same Boundary-Condition Test but limited to the time of the active waste event.

There are numerous issues that can be diagnosed by applying the Boundary-Condition Test Method leveraging multiple datasets including interval metering readings (kWh, kW, Amps, etc.) without the need for a high frequency meters.

As an additional example, in one embodiment, the system gets live data from people locations data streams and estimates the appropriate kWh consumption in light of the current occupancy level as well as the current weather conditions to determine whether waste exists and by how much.

In one embodiment, the system is used for business analytics internally by utility companies. The system gets all interval data of all their meters, then overlays it with the gathering and inferring of weather data, location visits data, people location data, or other building information such as business hours and popular times, etc.

Then, the system analyzes each meter's interval data to estimate hourly waste, trends, and waste events, diagnose probable issues/conditions in each building and determines whether they are driving the waste event and consumption of each building. These insights will be used in fully or in partial for business decisions and running different programs. This includes and not limited to determining which hours, customers, verticals, etc. impact peak demand with the highest amount of waste, by how much, for what reasons, etc. A utility company (or a smart city) would use these insights for a host of business purposes whether operational or customer facing.

As noted, one advantage of the system discussed herein is the identification of waste. When waste issues are addressed, it reduces wasted energy. This results in a less loaded utility grid. This is of a great importance especially for the peak demand hours. It has the additional benefit to the Load Serving Entity (AKA utility company) of reducing energy costs, maintenance demands, improved business decisions, targeted marketing, and customer programs, etc. Accordingly, this system is of a benefit to multiple entities, including direct and indirect, before and after the meter applications.

In one embodiment, the system uses the people locations data, live and/or historical, to understand occupancy patterns of buildings, and then use that in the analytics of performed by the system. Specifically, in one embodiment the system utilizes mobility data to predict building conditions, such as building occupancy. Mobility data is location data which tracks or logs an individual's location. The location is obtained using a user's wireless device. The device can be a smart phone, tablet, computer, smart watch, and other such devices. The devices can be Bluetooth, WiFi, cellular, or other similar connection whereby location can be determined. Location can be determined via GPS, cellular tower, WiFi coordinates, and other such methods. Mobility data can be collected in many forms. The data can be collected directly from the user. The data can be collected by third-parties such as application operators which obtain data from the individual and then subsequently sell such data. Additionally, the data can be housed and stored which is directly obtained from the individual. The mobility data, in whichever form, is first collected. After the data is collected, the analysis is conducted to determine the building operations. This can include building occupancy, whether the building is open or closed, etc. As noted, below, by recognizing who and how many people are in a location, the system can determine if the building is open, closed, etc.

In one such embodiment, the system gathers intelligence about buildings and makes predictions as to how the building is being used (live), or had been used in the past, at any given time. The following are some unlimiting example of the intelligence the system provides. Example-1: if the building is unoccupied per the mobility data within the closed hours of the business, then the system can predict that the BMS should be at setback mode and consuming only baseload. Example-2: if mobility data indicate that the building is at a peak use where occupancy is higher than 80%, AND the outside temperature is well higher than 80 F, the system can predict that the building is in cooling mode to accommodate these demanding factors. Example-3: some insights for repair vendors or CMMS software is to determine the best time to schedule a visit. This involves finding the hours that meet the repair needs such as open or closed for business, lowest number of visitors, number of hours needed for the repair visit, etc.

This remote building intelligence is done by analyzing the data the system gathers, regardless of if smart meter data is available or not, then structuring the data in time series, then deriving insights about the building and its use. The prediction can identify the number of visits, number of visits per device or person, the length of a visit, the number of employees, for example, isolating the devices which visit the buildings off business hours or those who visit the building on a regular basis and stay for an extended period of time. It should be noted that when discussing predictions, predictions can include objective data such as numbers. However, predictions can also include visualizations, dashboard visualizations etc. which provide relative information rather than concrete numbers.

The system can also predict the number of employees per shift by the number of devices identified as employees which are present in the building concurrently. Another example: using the mobility data in combination with weather data to predict demand of building consumption. The two demanding factors provide a good demand prediction and forcast for dashboard visualization, grid balancing, etc. Even without being coupled to meter data, by using mobility data and weather data, the energy peak, as an example, can be predicted. Thus, while the system may not be able to predict precise energy consumption value, it can predict the timing of peak energy demand. It may predict peak energy consumption based upon location data and the weather data. Far more accurate prediction can be had by basing the prediction on mobility data as well as weather data.

As but one example, the mobility data supplements the weather data by predicting the operation status. The operation status can be open or closed, busy hours, lunch hours, etc. People in the building increase energy consumption. They open doors which let cool air, or hot air, escape. They demand lighting, and their body temperatures increase the temperature of the building. As noted, the mobility data can offer insight as to the various hours of a building. The first hour opening a building can be different than the last hour, lunch hour, etc. Thus, having mobility data along with weather provides more accurate predictions. Thus, knowing if people are present, how many are present, etc., offers a better prediction even in the absence of meter data. In other embodiments, however, meter data can be used to further enhance the prediction.

The system can even evaluate the types of hours operating the building based on several attributes. This can include whether the business was open or closed by comparing the public business hours with the type of building or business along with the demographics of the people present in the building during that hour. As an example, if only staff is in the building, this can happen during open business hours or closed business hours. However, if the building is unoccupied, this is typically not during business hours. The system can review the total number of staff-only hours along with the total number of business hours and unoccupied hours. The building's demand for energy index is an aggregate percentage which represents the total demand for energy based on the percentage of at least two demanding factors (such as weather temperature and building occupancy rate). This specific building's demand analysis takes into account the time period, the need for cooling or heating, etc. This demand analysis is used for predicting the energy consumption trends. It can predict the HVAC status such as setback-cooling, setback-heating, startup/shoulder mode, shutdown/shoulder mode, active-cooling, active-heating, partially active (free cooling). Similarly, it can also predict the lighting status such as indoor lighting—fully lit, indoor lighting—emergency lighting active, outdoor lighting—fully lit, outdoor lighting—emergency lighting active, outdoor lighting—off.

Indexing of Demanding Factors

In multiple embodiments where occupancy is needed to estimate energy consumption, a real measurement of number of people in the building's vicinity is often needed. However, sometimes the mobility data is only available as a percent (0-1.0) and is referred to as Popularity Data or Popularity Times. These percentage values can't be used to estimate actual energy consumption values (kWh). Consequently, there is a need for a method to allow using the percentages to calculate consumption (or other similar values). When multi-variant regression is used to estimate the value of consumption, the following equation is the result:

Consumption=Constant+a(Number of Occupants)+b(Temperature Spread in F)+error

Consumption=Constant+a(Number of Occupants)+b(Absolute [Temperature in F−65 F])+error

Consumption is the energy consumption dependent variable measured in kWh. Constant is an attribute to each building or meter load representing the baseload. “a” is the multiplier of the occupancy which measures the impact of 1 person change in occupancy on the Consumption (the dependent variable). “b” is the multiplier of the temperature which measures the impact of 1 degree temperature change on the Consumption (the dependent variable). The Temperature Spread is the spread of the current temperature value from the neutral 65 F.

When Popularity data is used, it represents the current occupancy value relative to the maximum historically common value. For example: if an office building has hosted in the past a maximum number of 100 people, and the current occupancy is at 30 people, that means that the current popularity is 0.3.

The multi-variant regression can be used with percentages by converting all independent variables to percentages as well.

Consumption=Constant+c(Popularity Percent)+d(Temperature Spread Percent)+error

Temperature Spread Percent is used to calculate this percentage accurately. Here, in one embodiment, we separate the cooling weather from heating weather. Each weather will result in a different regression formula. Accordingly, when the temperature is below 65 F, the following formula can be used:

Consumption=Constant+ch(Popularity Percent)+dh([65−Current Temperature]/[65−lowest Temperature])+error

Here, consumption is the energy consumption dependent variable measured in kWh. The constant is an attribute to each building or meter load representing the baseload. “ch” is the multiplier of the Popularity Percent which measures the impact of 1 percent change in occupancy level on the Consumption during heating weather. “dh” is the multiplier of the temperature which measures the impact of 1 percent change in the Temperature Spread Percent on the heating Consumption.

Conversely, when temperature is higher than 65 F, the following formula can be utilized:

Consumption=Constant+ch(Popularity Percent)+dh([Current Temperature−65 F]/[lowest Temperature−65 F])+error

Here, Consumption is the energy consumption dependent variable measured in kWh. Constant is an attribute to each building or meter load representing the baseload. “cc” is the multiplier of the Popularity Percent which measures the impact of 1 percent change in occupancy level on the Consumption during cooling weather. “dc” is the multiplier of the temperature which measures the impact of 1 percent change in the Temperature Spread Percent on the cooling Consumption.

While the invention has been particularly shown and described with reference to a preferred embodiment, it will be understood by those skilled in the art that various changes in form and detail may be made therein without departing from the spirit and scope of the invention. As the system described here is focused on energy consumption, same concept is applied to all utility metered data by making appropriate modifications. This invention if for all utility types including and not limiting to electricity, gas, district cooling, district heating, water, etc.

### Additional Description

The following clauses are offered as further description of the disclosed invention.
Clause 1. A method of detecting waste, said method comprising the steps of:
a) collecting metered utility data;
b) normalizing said utility data against at least two demand factors;
c) predicting appropriate utility usage based on at least two demand factors;
d) estimating waste.
   Clause 2. The method of any proceeding or preceding clauses wherein said normalizing includes basing said normalizing on building usage and weather.
   Clause 3. The method of any proceeding or preceding clauses wherein said normalizing of step b) occurs at least once every hour.
   Clause 4. The method of any proceeding or preceding clauses wherein said predicting comprises comparing current hour utility data with similar times having similar demand factors to yield an appropriate utility usage.
   Clause 5. The method of any proceeding or preceding clauses wherein said at least two demand factors includes data from local and connected weather sensors.
   Clause 6. The method of any proceeding or preceding clauses wherein said predicting comprises coupling with a computerized maintenance and management system.
   Clause 7. The method of any proceeding or preceding clauses wherein said estimating waste comprises comparing the metered utility data and predicted appropriate value.
   Clause 8. The method of any proceeding or preceding clauses wherein said estimating waste comprises applying periodicity to discern patterns.
   Clause 9. The method of any proceeding or preceding clauses further comprising e) taking correction action to reduce waste.
   Clause 10. The method of any proceeding or preceding clauses further comprising converting estimated waste resulting from said estimating step to quantified financial impact.
   Clause 11. The method of any proceeding or preceding clauses further comprising converting estimated waste resulting from said estimating step to quantified economic impact.
   Clause 12. The method of any proceeding or preceding clauses further comprising using estimated waste resulting from said estimating step as an input for a maintenance management system.
   Clause 13. The method of any proceeding or preceding clauses wherein the maintenance management system has a plurality of job items and further comprising the step of utilizing said estimated waste to prioritize said job items.
   Clause 14. The method of any proceeding or preceding clauses wherein said predicting comprises coupling with a building management system.
   Clause 15. The method of any proceeding or preceding clauses further comprising using the building management system and the predicted waste to locate faults and verify the faults have been corrected.
   Clause 16. The method of any proceeding or preceding clauses further comprising the steps of:
e) determining a minimum amount of waste to target in a portfolio of monitored systems;
f) identify the systems which meet the minimum amount of waste;
g) taking corrective action.
   Clause 17. The method of any proceeding or preceding clauses wherein said demand factors include outside temperature, inside temperature, building schedule, and building usage data.
   Clause 18. The method of any proceeding or preceding clauses wherein building usage data comprises occupancy.
   Clause 19. The method of any proceeding or preceding clauses wherein said metered utility data comprises data related to electricity in kWh.
   Clause 20. The method of any proceeding or preceding clauses wherein said building usage data is obtained from API's.
   Clause 21. The method of any proceeding or preceding clauses wherein said collecting metered utility data comprises collecting data from only a single meter.
   Clause 22. The method of any proceeding or preceding clauses wherein said collecting metered utility data comprises collecting data from a plurality of meters.
   Clause 23. A system for detecting waste, said system comprising:
a meter for collecting current meter utility data;
a sensor for recording at least one demand factor;
a database for storing historical meter utility data and at least two demand factors associated with said historical meter utility data;
a processor for predicting appropriate energy usage based on at least two demand factors.
   Clause 24. A method of detecting waste, and diagnosing buildings' conditions and waste potential causes using utility metering interval data; said method comprising the steps of:
   a) Collecting and monitoring metered utility interval data;
   b) Collecting and monitoring building data
   c) Collecting and monitoring geospatial data
   d) Collecting and monitoring at least two demanding factors data
   e) Normalize the consumption against at least two demanding factors
   f) Predicting appropriate utility usage based on at least two demand factors
   g) Estimating hourly waste
   h) Identifying persistence waste patterns
   i) Correlating waste pattern with other systems' events
   j) Diagnosing for building conditions using the Boundary-Condition Tests
   Clause 25. The method of any proceeding or preceding clauses wherein said collecting and monitoring metered utility interval data comprises of hourly interval readings or shorter intervals (intervals equal or less than 60 minutes) that are timestamped.
   Clause 26. The method of any proceeding or preceding clauses wherein said collecting and monitoring metered utility interval data comprises of data from the local building meters, the building management system, utility company IT infrastructure or any other source.
   Clause 27. The method of any proceeding or preceding clauses wherein said collecting and monitoring metered utility interval data comprises of data transferred digitally to the invented system or user's tools, and
   Clause 28. The method of any proceeding or preceding clauses wherein interval data comprises of data uploaded manually to the invented system.
   Clause 29. The method of any proceeding or preceding clauses wherein said collecting and monitoring building data comprises of hours of business, hours of different modes of operations, business type, and other information about the building.
   Clause 30. The method of any of the proceeding or preceding clauses wherein said collecting and monitoring hours of business, hours of different modes of operations, business type, and other information about the building comprises of scrapping webpages and web directories, published business hours on businesses websites, maps such as google maps and Microsoft Bing Maps, or other similar data sources.
   Clause 31. The method of any of the proceeding or preceding clauses wherein said collecting and monitoring hours of different modes of operations is by applying industry best practices for each type of building to the hours of the business. For example; best practice for an office building is to start equipment 1 hour before opening. Thus, the system will schedule the presumed equipment startup time one hour before the opening hour for public business.
   Clause 32. The method of any of the proceeding or preceding clauses wherein said collecting and monitoring hours of business, hours of different modes of operations comprises of analyzing the people location data and other geospatial data to conclude probable operations mode from people activity patterns.
   Clause 33. The method of any of the proceeding or preceding clauses wherein said collecting and monitoring building data is done at least once per week, and it can be every day, hour or live stream of data.
   Clause 34. The method of any of the proceeding or preceding clauses wherein said collecting and monitoring building data is obtained via web scrapping and software automation.
   Clause 35. The method of any of the proceeding or preceding clauses wherein said collecting and monitoring building data is obtained via APIs or other automated digital transfer methods of data.
   Clause 36. The method of any of the proceeding or preceding clauses wherein said collecting and monitoring hours of business is obtained via web scrapping and software automation
   Clause 37. The method of any of the proceeding or preceding clauses wherein said collecting and monitoring hours of business is obtained via APIs or other automated digital transfer of data
   Clause 38. The method of any of the proceeding or preceding clauses wherein said collecting and monitoring hours of different modes of operations is obtained via APIs or other automated digital transfer methods of data.
   Clause 39. The method of any of the proceeding or preceding clauses wherein said collecting and monitoring hours of business and hours of different modes of operations comprises of connecting with other enterprise systems such as employee scheduling and building management systems.
   Clause 40. The method of any of the proceeding or preceding clauses wherein said collecting and monitoring hours of business and hours of different modes of operations comprises of analyzing unique identifier (device) historical location data to derive the building usage pattern such as: open for business, setback mode (unoccupied mode), employee only mode, etc.
   Clause 41. The method of any of the proceeding or preceding clauses wherein said collecting and monitoring geospatial data comprises of people location data from cellphone sensors, smartphone applications, Wi-Fi data, Bluetooth data, local event data, and other data associated with the geographical location.
   Clause 42. The method of any of the proceeding or preceding clauses wherein said collecting and monitoring Geospatial data comprises of foot traffic data into the building's footprint or the surrounding vicinity (via geofencing)
   Clause 43. The method of any of the proceeding or preceding clauses wherein said foot traffic comprises of time-stamped total number of people in the location for every hour.
   Clause 44. The method of any of the proceeding or preceding clauses wherein said foot traffic comprises of average indexed popularity for each hour of the week shown as a percent (or zero to one).
   Clause 45. The method of any of the proceeding or preceding clauses wherein said indexed popularity for each hour of the week comprises of live popularity index compared to the average popularity index for each hour.
   Clause 46. The method of any of the proceeding or preceding clauses wherein said collecting and monitoring Geospatial data comprises of time stamped historical location data for each user, phone, or application identified via unique identifier.
   Clause 47. The method of any of the proceeding or preceding clauses wherein said collecting and monitoring Geospatial data comprises of analyzing the behavior of each unique identifier (device) as it relates to the building. Such analysis includes but not limited to whether each identifier is an employee or a visitor, a onetime visitor a returning visitor, an overnight guest at a hotel, etc.
   Clause 48. The method of any of the proceeding or preceding clauses wherein said collecting and monitoring Geospatial data comprises of analyzing the behavior of each unique identifier (device) as it relates to each visit such as length of visit, number of visits in a day or week (or similar), paired visitors, etc.
   Clause 49. The method of any of the proceeding or preceding clauses wherein said collecting and monitoring Geospatial data comprises of data transferred digitally to the invented system or user's tools.
   Clause 50. The method of any of the proceeding or preceding clauses wherein said collecting and monitoring Geospatial data comprises of data uploaded manually to the invented system.
   Clause 51. The method of any of the proceeding or preceding clauses wherein said collecting and monitoring demanding factors data comprises of weather data and building occupancy (or vicinity foot traffic) data.
   Clause 52. The method of any of the proceeding or preceding clauses wherein said collecting and monitoring weather data comprises of hourly weather data or shorter intervals (intervals equal or less than 60 minutes) that are timestamped
   Clause 53. The method of any of the proceeding or preceding clauses wherein said collecting and monitoring weather data comprises of a minimum of dry bulb temperature and humidity
   Clause 54. The method of any of the proceeding or preceding clauses wherein said collecting and monitoring weather data is via building sensors.
   Clause 55. The method of any of the proceeding or preceding clauses wherein said collecting and monitoring weather data is via connecting with the building management system.
   Clause 56. The method of any of the proceeding or preceding clauses wherein said collecting and monitoring weather data is via API with third party weather data providers.
   Clause 57. The method of The method of any of the proceeding or preceding clauses wherein said collecting and monitoring building occupancy (or vicinity foot traffic) data comprises of time-stamped number of people within a specified radius of the building location.
   Clause 58. The method of any of the proceeding or preceding clauses wherein said collecting and monitoring building occupancy data is obtained via building occupancy counters or building systems (building management system, reservation system, etc.).
   Clause 59. The method of any of the proceeding or preceding clauses wherein said collecting and monitoring building occupancy (or vicinity people traffic) data comprises of people location data.
   Clause 60. The method of any of the proceeding or preceding clauses wherein said collecting and monitoring people location data comprises time-stamped individual people location coordinates or similar geospatial attributes (address, etc.)
   Clause 61. The method of any of the proceeding or preceding clauses wherein said collecting and monitoring people location data comprises place popular times metrics such as what is published on Google maps Popular Times section.
   Clause 62. The method of any of the proceeding or preceding clauses wherein said collecting and monitoring people location data comprises people location data provided by third party sources
   Clause 63. The method of any of the proceeding or preceding clauses wherein said collecting and monitoring people location data comprises data captured by cell phone application installed on the utility customer cellphone.
   Clause 64. The method of any of the proceeding or preceding clauses wherein said collecting and monitoring people location data is obtained via web scrapping and software automation
   Clause 65. The method of any of the proceeding or preceding clauses wherein said collecting and monitoring people location data is obtained via APIs or other automated digital transfer methods of data.
   Clause 66. The method of any of the proceeding or preceding clauses wherein said collecting and monitoring demanding factors is done at least once per week.
   Clause 67. The method of any of the proceeding or preceding clauses wherein said collecting and monitoring demanding factors comprises of visualizing the data of demanding factors on heatmap—or similar dashboard or report- to identify the total demand patterns on the grid in a specific territory, time, etc.
   Clause 68. The method of any of the proceeding or preceding clauses wherein said collecting and monitoring demanding factors comprises of aggregating the impact of at least two demanding factors into a single index that can be used to analyze or visualize the total demand of a specific geographical territory for a specific scenario such as peak load, etc.
   Clause 69. The method of any of the proceeding or preceding clauses wherein said normalizing of step e) is applied to the hourly interval data.
   Clause 70. The method of any of the proceeding or preceding clauses wherein said normalizing consumption comprises of multivariance analyses to identify the consumption impact of a single temperature change or a single foot traffic change.
   Clause 71. The method of any of the proceeding or preceding clauses wherein said normalizing consumption comprises of identifying the consumption impact of a single temperature change or a single foot traffic change for segmented condition to achieve the highest accuracy possible in the predictions. Segmentation of conditions are based on different hours, building modes of operations, temperature ranges, or other conditions.
   Clause 72. The method of any of the proceeding or preceding clauses wherein said predicting appropriate utility usage comprises of analyzing historical collected and calculated data (steps 1-a through 1-e) and identify the meter's historical consumption values in response to different operational conditions and demanding factors.
   Clause 73. The method of any of the proceeding or preceding clauses wherein said predicting appropriate utility usage comprises of identifying the high running efficiency (i.e., lowest utility consumption) the building can achieve for at the current operational conditions and demanding factors.
   Clause 74. The method of any of the proceeding or preceding clauses wherein said predicting appropriate utility usage comprises of using multivariance models to predict the consumption of a specific combination of at least two demanding factors; weather and building usage data.
   Clause 75. The method of any of the proceeding or preceding clauses wherein said predicting appropriate utility usage comprises of using multivariance models to predict the consumption of the current two demanding factors.
   Clause 76. The method of any of the proceeding or preceding clauses wherein said predicting appropriate utility usage comprises of using multivariance models to predict the consumption of the future forecasted values of two demanding factors.
   Clause 77. The method of any of the proceeding or preceding clauses wherein said predicting appropriate utility usage comprises of aggregation of the predicted values at a regional, portfolio, or grid level to forecast demand on the utility infrastructure.
   Clause 78. The method of any of the proceeding or preceding clauses wherein said predicting appropriate utility usage comprises of using machine learning techniques to predict most probable utility consumption value in response to specific current or forecasted demanding factors values.
   Clause 79. The method of any of the proceeding or preceding clauses wherein said predicting appropriate utility usage comprises of using one or combination of multiple methods to obtain the possible consumption values. Machine learning, multivariant regression, time series regression, and many other possible methods can be used.
   Clause 80. The method of any of the proceeding or preceding clauses wherein said estimating hourly waste comprises comparing the metered utility data and predicted appropriate usage value. The difference between the two values is a representation of the maximum waste value or efficiency gained.
   Clause 81. The method of any of the proceeding or preceding clauses wherein said identifying persistence waste pattern comprises of identifying the characteristics of waste as an event which includes starting and ending dates, active hours and days, daily waste amount, etc.
   Clause 82. The method of any of the proceeding or preceding clauses wherein said identifying persistence waste pattern comprises user select a specific periodicity criterion stating the hours of the week, the daily waste amount of those hours, and frequency of days exceeding the daily waste threshold for those hours. See FIG. 4 for the algorithm logic
   Clause 83. The method of any of the proceeding or preceding clauses wherein said identifying persistence waste pattern comprises of using a dynamic periodicity criterion where the user specifies one attribute of waste pattern, and the algorithm completes the periodicity criteria based on the actual data. For example: the user selects the top 10% of waste. the algorithm will identify the hours that represent highest 10% of hourly waste values, then determine if those hours take place on one, two or more days (frequency of wasteful days), then sum the daily waste amount for those hours to determine the amount component of the periodicity criteria. Artificial intelligence can be used in deploying dynamic periodicity search.
   Clause 84. The method of any of the proceeding or preceding clauses wherein said correlating waste pattern with other systems' events comprises sharing waste data (hourly, daily, waste events, etc.) with other event recording systems, while receiving data of the other events to this system (coupling)
   Clause 85. The method of any of the proceeding or preceding clauses wherein said correlating waste pattern with other systems' events comprises coupling with computerized maintenance management system (CMMS), building management systems BMS (also known as, building automation system BAS, or energy management system EMS), employee schedule system, business operation schedule systems, etc.
   Clause 86. The method of any of the proceeding or preceding clauses wherein said correlating waste pattern with other systems' events comprises displaying the shared and correlation data on a dashboard or mobile application accessed by a user. Waste event data, waste quantity data; aggregated, indexed, or benchmarked data displayed on event recording systems's user interface.
   Clause 87. The method of any of the proceeding or preceding clauses wherein said coupling with other systems comprises of different ways and not limited to them being separate systems. It also comprises of our system/method being incorporated into the other system as one system.
   Clause 88. The method of any of the proceeding or preceding clauses further comprising taking corrective action to reduce waste. corrective action comprises of human conducting investigation and completing the action.
   Clause 89. The method of any of the proceeding or preceding clauses further comprising taking corrective action to reduce waste. corrective action comprises of automatic adjustment via automation systems.
   Clause 90. The method of any of the proceeding or preceding clauses further comprising converting estimated waste resulting from said estimating step to quantified financial impact.
   Clause 91. The method of any of the proceeding or preceding clauses further comprising converting estimated waste resulting from said estimating step to quantified economic and environmental impact.
   Clause 92. The method of any of the proceeding or preceding clauses wherein the maintenance management system has a plurality of job items and further comprising the step of utilizing said estimated waste to prioritize said job items. Estimated waste comprises of waste event data, waste quantity data; aggregated, indexed, or benchmarked formats.
   Clause 93. The method of any of the proceeding or preceding clauses wherein said predicting comprises coupling with a building management system or incorporate into the building management system at the code level.
   Clause 94. The method of any of the proceeding or preceding clauses further comprising using the building management system and the predicted waste to locate faults and verify the faults have been corrected.
   Clause 95. The method of any of the proceeding or preceding clauses further comprising the steps of:
   a. determining a minimum amount of waste to target in a portfolio of monitored systems;
   b. identify the systems which meet the minimum amount of waste;
   c. taking corrective action.
   Clause 96. The method of any of the proceeding or preceding clauses wherein said demand factors include outside temperature, inside temperature, building schedule, and building usage data, occupancy patterns.
   Clause 97. The method of any of the proceeding or preceding clauses wherein building usage data comprises occupancy.
   Clause 98. The method of any of the proceeding or preceding clauses wherein said metered utility data comprises data related to electricity in kWh.
   Clause 99. The method of any of the proceeding or preceding clauses wherein said building usage data is obtained from API's.
   Clause 100. The method of any of the proceeding or preceding clauses wherein said collecting metered utility data comprises collecting data from only a single meter.
   Clause 101. The method of any of the proceeding or preceding clauses wherein said collecting metered utility data comprises collecting data from a plurality of meters.
   Clause 102. A system for detecting waste, said system comprising:
   a. a meter for collecting current meter utility data;
   b. a sensor for recording at least one demand factor;
   c. a database for storing historical meter utility data and at least two demand factors associated with said historical meter utility data;
   d. a processor for predicting appropriate energy usage based on at least two demand factors.
   Clause 103. The method or system of any of the proceeding or preceding clauses wherein said system find insights about the building operations such as modes of operations, delivery times, employee only times, etc.
   Clause 104. The method or system of any of the proceeding or preceding clauses wherein said system provides additional insights on top of waste, such as building operational insights, structure the data and store for ease access.
   Clause 105. The method or system of any of the proceeding or preceding clauses wherein said system comprises tools and analytics for diagnostic capabilities.
   Clause 106. The method or system of any of the proceeding or preceding clauses wherein said system is coupled, either via a wire or wireless, to databases to pull necessary information.
   Clause 107. The method or system of any of the proceeding or preceding clauses wherein said system collects business hours from multiple sources (scrapping vs APIs VS inferred from traffic patterns) and then determines which one is most updated and accurate.
   Clause 108. The method or system of any of the proceeding or preceding clauses wherein said system allows analysis to occur at least once every day, and can occur at interval to match the shortest interval in all data gathered.
   Clause 109. A method of remote sensing and intelligence gathering of current or historical building operations, building conditions, occupants behavior using diverse sources of data; said method comprising the steps of:
   a) Collecting and monitoring building data
   b) Collecting and monitoring geospatial data
   Clause 110. A method for collecting intelligence about buildings, said method comprises of:
   1. Collecting demanding factors
   2. Collecting geospatial data and people location data
   3. Collect business hours
   4. Structure the data in timeseries
   5. Analyzing the data to find insights about the building use, operation, staffing, visitor demographics, etc.
   6. Apply building engineering and operations best practices and code requirements to derive further insights about the building's systems, demand for energy forecast, etc.
   7. If utility interval data is available, compare utility consumption and demand trend against the collected building intelligence.
   8. Provide recommendations specific to utility data, building
   Clause 111. A system that is a repository of Building Intelligence using the data gathered.
   Clause 112. The system or method of any proceeding or preceding claim where data is downloaded.
   Clause 113. The system or method of any proceeding or preceding claim where data is transferred via API or other similar digital method.
   Clause 114. The system or method of any proceeding or preceding claim wherein said system comprises a search engine for intelligence about a specific building, type of buildings, regional, or any search criteria.
   Clause 115. The system or method of any proceeding or preceding claim wherein said system utilizes user types in the building address, business type, and region (zip code, city, state, area selected via map interface, etc.).
   Clause 116. The system or method of any proceeding or preceding claim wherein said system displays the insight provided.
   Clause 117. A method comprising the steps of:
   a) obtaining mobility data;
   b) Predicting building conditions based on said mobility data.
   Clause 118. The method of clause 117 wherein said predicting comprises structuring the data in time series.
   Clause 119. The method of clause 117 wherein said building conditions comprise building usage.
   Clause 120. The method of claim 117 wherein said building conditions comprise predicting the length of a visit.
   Clause 121. The method of claim 117 wherein said building conditions comprises whether a building is open or closed.
   Clauses 122. The method of claim 117 further comprising the step of analyzing data from a meter.
   Clause 123. The method of claim 117 wherein said mobility data is obtained through an API. Clause 124. The method of claim 117 wherein said mobility data is historical.
   Clause 125. The method of claim 117 wherein said building conditions comprise whether the building is in cooling mode.
   Clause 126. The method of claim 117 wherein said mobility data is live.

1. A method of detecting waste, said method comprising the steps of:
a) collecting metered utility data;
b) normalizing said utility data against at least two demand factors;
c) predicting appropriate utility usage based on at least two demand factors;
d) estimating waste.

2. The method of claim 1 wherein said normalizing includes basing said normalizing on building usage and weather.

3. The method of claim 1 wherein said predicting comprises comparing current hour utility data with similar times having similar demand factors to yield an appropriate utility usage.

4. The method of claim 1 wherein said at least two demand factors includes data from local and connected weather sensors.

5. The method of claim 1 wherein said estimating waste comprises comparing the metered utility data and predicted appropriate value.

6. The method of claim 1 wherein said estimating waste comprises applying periodicity to discern patterns.

7. The method of claim 1 further comprising e) taking correction action to reduce waste.

8. The method of claim 1 further comprising converting estimated waste resulting from said estimating step to quantified financial impact.

9. The method of claim 1 further comprising using estimated waste resulting from said estimating step as an input for a maintenance management system.

10. The method of claim 1 wherein said predicting comprises coupling with a building management system.

11. The method of claim 1 further comprising the steps of:
e) determining a minimum amount of waste to target in a portfolio of monitored systems;
f) identify the systems which meet the minimum amount of waste;
g) taking corrective action.

12. The method of claim 1 wherein said demand factors include outside temperature, and building usage data.

13. The method of claim 12 wherein building usage data comprises occupancy data.

14. A system for detecting waste, said system comprising:
a meter for collecting current meter utility data;
a sensor for recording at least one demand factor;
data connectivity to exchange data with other systems and sources
a database for storing historical meter utility data and at least two demand factors associated with said historical meter utility data;
a processor for predicting appropriate energy usage based on at least two demand factors.

15. A method comprising the steps of:
a) obtaining mobility data;
b) predicting building conditions based on said mobility data.

16. The method of claim 15 further comprising obtaining weather data and building usage data, and wherein said predicting building conditions is based on said mobility data and said weather data.

17. The method of claim 15 wherein said building conditions comprise building usage.

18. The method of claim 15 wherein said building conditions comprises whether a building is open or closed or any inferred condition of the building.

19. The method of claim 15 further comprising the step of analyzing data from a meter.
